(19) United States
(12) Patent Application Publication
(10) Pub. No.: US 2015/0287843 A1
(43) Pub. Date: Oct. 8, 2015

(54) SOLAR CELL WITH DIELECTRIC LAYER

(71) Applicant: TSMC SOLAR LTD., Taichung City (TW)

(72) Inventor: Tzu-Huan CHENG, Kaohsiung City (TW)

(73) Assignee: TSMC SOLAR LTD., Taichung City (TW)

(21) Appl. No.: 14/244,016

(22) Filed: Apr. 3, 2014

(51) Int. Cl. H01L 31/0216; H01L 31/18; H01L 31/0296; H01L 31/0224

(52) U.S. Cl. CPC H01L 31/02167; H01L 31/022433; H01L 31/1828; H01L 31/0296

(57) ABSTRACT

A solar cell includes a back contact layer, an absorber layer above the back contact layer, a dielectric layer above the absorber layer, and a front contact layer above the dielectric layer.

### PRIORITY CLAIM AND CROSS-REFERENCE

None.

### BACKGROUND

This disclosure relates to thin film photovoltaic solar cells, and methods of fabricating solar cells. Solar cells are electrical devices for generation of electrical current from sunlight by the photovoltaic (PV) effect. Thin film solar cells have one or more layers of thin films of PV materials deposited on a substrate. The film thickness of the PV materials can be on the order of nanometers or micrometers.

Examples of thin film PV materials used as absorber layers in solar cells include copper indium gallium selenide (CIGS) and cadmium telluride. Absorber layers absorb light for conversion into electrical current. Solar cells also include front and back contact layers to assist in light trapping and photo-current extraction and to provide electrical contacts for the solar cell. The front contact typically comprises a transparent conductive oxide (TCO) layer. The TCO layer transmits light through to the absorber layer and conducts current in the plane of the TCO layer. In some systems, a plurality of solar cells are arranged adjacent to each other, with the front contact of each solar cell conducting current to the next adjacent solar cell. Each solar cell includes an interconnect structure for conveying charge carriers from the front contact of a solar cell to the back contact of the next adjacent solar cell on the same panel.

Some solar cells include a buffer layer, to prevent shunting (and current leakage) between the front contact and the back contact. The buffer layer forms part of a p-n junction, along with the absorber layer. For example, in a solar cell having a CIGS absorber, a buffer layer of CdS or ZnS can be formed on the absorber layer, before forming the TCO layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a solar cell, in accordance with some embodiments.

FIG. 2 is a flow chart of a method of making the solar cell of FIG. 1, in accordance with some embodiments.

FIG. 3 is a cross-sectional view of another solar cell, in accordance with some embodiments.

FIG. 4 is a flow chart of a method of making the solar cell of FIG. 3, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The efficiency of a solar cell can be limited by the trade-off between open circuit voltage (Voc) and short circuit current (Jsc). A higher carrier concentration and thicker buffer layer are beneficial for providing a higher electrical field, and result in higher Voc. But a thicker buffer layer decreases the light transmission to the absorber and results in lower Jsc. On the other hand, a thinner buffer layer increases light transmission, but may cause shunting and high leakage current of the pn junction.

This disclosure describes examples of embodiments in which the buffer layer material of a thin film photovoltaic solar cell is replaced by a dielectric layer, with or without a thin embedded buffer material layer. A dielectric layer with a small thickness can support a large electrical field (and thus a high open circuit voltage, Voc). The dielectric layer can perform the buffer layer function of preventing shunts (leakage) between the front contact and the back contact of the solar cell. In some embodiments, a dielectric layer is formed over an absorber layer having a high quality top surface, without a separate passivation layer therebetween. In other embodiments, a two-part buffer is formed on the absorber, including a thin embedded buffer layer of CdS or ZnS for passivation, and a dielectric layer formed on the embedded buffer layer to prevent shunts.

In some embodiments, the buffer layer is provided by a dielectric material having high optical transmittance, such as SiO₂ or Al₂O₃. In some embodiments, the total thickness of the dielectric layer (or dielectric layer and embedded CdS or ZnS buffer layer) is less than the thickness used for a buffer layer containing CdS or ZnS alone, without the dielectric layer. This reduced thickness reduces the absorption of photons by the dielectric layer (or dielectric layer and embedded CdS or ZnS buffer layer), so that a Voc can be maintained or increased without reducing photon collection. Overall solar cell efficiency can be increased.

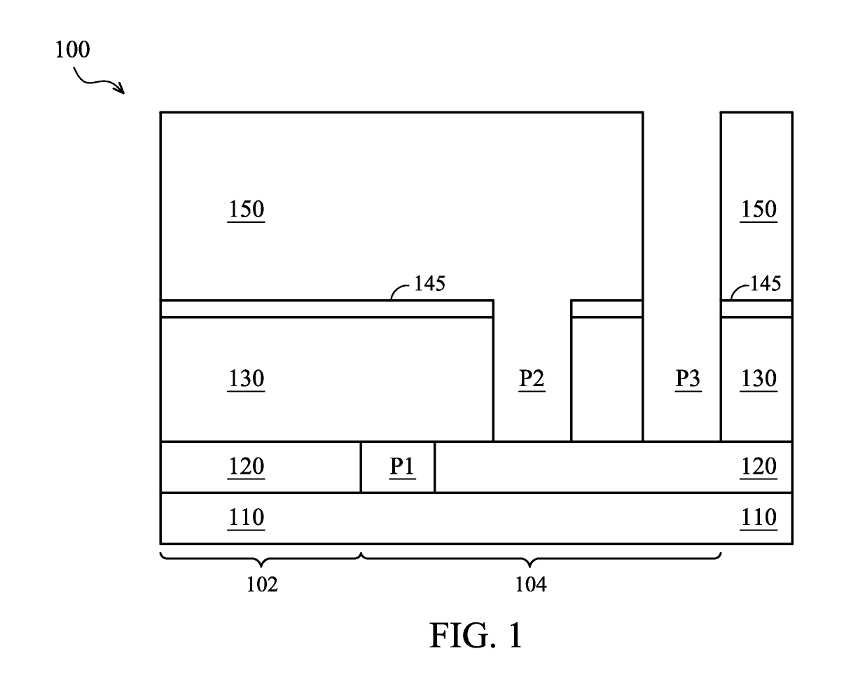

FIG. 1 is a cross-sectional view of a solar panel 100, in accordance with some embodiments. The solar panel 100 includes a solar panel substrate 110, a back contact layer 120 on the substrate, an absorber layer 130 over the back contact layer 120, a dielectric layer 145 over the absorber layer 130, and a front contact layer 150 comprising a bulk transparent conductive material (such as a transparent conductive oxide, or TCO) over the dielectric layer 145.

Substrate 110 can include any suitable solar cell substrate material, such as glass. In some embodiments, substrate 110 includes a glass substrate, such as soda lime glass, or a flexible metal foil or polymer (e.g., a polyimide, polyethylene terephthalate (PET), polyethylene naphthalene (PEN) polymeric hydrocarbons, cellulosic polymers, polycarbonates, polyethers, or others.). Other embodiments include still other substrate materials.

The back contact layer 120 includes any suitable back contact material, such as metal. In some embodiments, back contact layer 120 can include molybdenum (Mo), platinum (Pt), gold (Au), silver (Ag), nickel (Ni), or copper (Cu). Other embodiments include still other back contact materials. In some embodiments, the back contact layer 120 has a thickness in a range from about 50 nm to about 2 μm. In some embodiments, the back contact layer is formed by sputtering.

The absorber layer 130 includes any suitable absorber material, such as a p-type semiconductor. In some embodiments, the absorber layer 130 can include a chalcopyrite-based material comprising, for example, Cu(In,Ga)Se₂ (CIGS), cadmium telluride (CdTe), CuInSe₂ (CIS), CuGaSe₂ (CGS), Cu(In,Ga)Se₂ (CIGS), Cu(In,Ga)(Se,S)₂ (CIGSS), CZTS, CdTe or amorphous silicon. Other embodiments include still other absorber materials. In some embodiments, the absorber layer 130 is from about 0.3 μm to about 8 μm thick. The absorber layer 130 can be applied using a variety of different process. For example, the CIGS precursors can be applied by sputtering. In other embodiments, one or more of the CIGS precursors are applied by evaporation.

In some embodiments, as shown in FIG. 1, the buffer layer is a dielectric layer 145 formed above the absorber layer 130. In some embodiments, as shown in FIG. 1, the dielectric layer 145 is formed directly on the absorber layer 130, and the front contact layer 150 is formed directly on the dielectric layer 145.

A dielectric material is a poor conductor of electricity, but an efficient supporter of electrostatic field. The dielectric layer 145 can further reduce the leakage current.

In some embodiments, the dielectric layer 145 comprises a material having a band gap greater than 3 eV. A higher band gap leads to low absorption of light in the dielectric layer 145. If the photon energy is less than the band gap, then the light is not absorbed by the dielectric. This allows more light to reach the absorber layer 130 for conversion to electricity.

In some embodiments, the dielectric layer comprises a material having a dielectric constant in a range from about 3 to about 11. A material having a dielectric constant in this range supports a greater electrical field without breakdown, permitting a high Voc with a thin dielectric layer 145. In some embodiments, the dielectric material is SiOₓ, Al₂O₃, or HfO₂.

The dielectric layer 145 is undoped, to provide a high resistivity (for preventing shunts). The transportation of charge carriers from the absorber layer 130 to the front contact 150 is by tunneling, so a thin dielectric layer 145 is used. The carrier transport via the quantum confinement tunneling effect contributes to a high Jsc and low interface resistance.

In some embodiments, the dielectric layer 145 has a thickness in a range from about 0.1 nm to about 10 nm. This range can support a desired electrical field strength while providing improved light transmittance compared to a buffer layer without a dielectric layer (such as a 100 nm layer of CdS or ZnS).

In other embodiments, the dielectric layer 145 has a thickness from 1 nm to 5 nm. A dielectric film 145 in this thickness range can better accommodate small surface defects and maintain a higher Voc than a dielectric layer 145 having a thickness less than 1 nm, while providing reduced photon absorption relative to a 10 nm dielectric film. In general the thinner the dielectric layer 145, the lower the absorption of photons will be in the dielectric layer. Because the absorption of photons by the dielectric layer is reduced, the absorber layer 130 can collect more photons, and provide a higher short circuit current Jsc. Thus, substitution of dielectric layer 145 for a buffer layer can maintain Voc and increase Jsc at the same time, compared to a solar cell having a CdS or ZnS buffer layer without the dielectric layer.

The dielectric layer 145 can be formed directly on the absorber layer 130 in solar cells 100 which do not require a CdS or ZnS buffer layer for purpose of passivation, and which do not require a buffer layer to form a p-n junction. For example, the dielectric layer 145 can be formed directly on the absorber layer in any solar cell 100 having an absorber layer 130 with a top surface of sufficiently high quality (i.e., with few surface defects) so that no CdS or ZnS buffer layer would be used, even in the absence of dielectric layer 145. The SiOₓ or Al₂O₃ dielectric layer 145 can bond sufficiently well with the absorber 130 to provide passivation for the small number of surface defects. The dielectric layer 145 prevents shunts while absorbing fewer photons than a buffer layer comprising CdS or ZnS, which can be much thicker than the dielectric layer 145.

In some embodiments, the dielectric layer 145 comprises a silicon oxide, an aluminum oxide or a hafnium oxide. Based on the band gaps of these three dielectric materials, SiOX and Al₂O₃ can provide lower leakage current than HfO₂. In some embodiments, the dielectric layer 145 is formed of silicon dioxide (SiO₂) or alumina (Al₂O₃). In other embodiments, the dielectric layer 145 is formed of another silicon oxide (SiOₓ).

In some embodiments, front contact layer 150 includes an annealed transparent conductive oxide (TCO) material. In some embodiments, the TCO layer 150 is highly doped. For example, the charge carrier density of the TCO layer 150 can be from about 1×10¹⁷ cm⁻³ to about 1×10¹⁸ cm⁻³. The TCO material for the annealed TCO layer can include any suitable front contact material, such as metal oxides and metal oxide precursors. In some embodiments, the TCO material can include zinc oxide (ZnO), cadmium oxide (CdO), indium oxide (In₂O₃), tin dioxide (SnO₂), tantalum pentoxide (Ta₂O₅), gallium indium oxide (GaInO₃), (CdSb₂O₃), or indium oxide (ITO). The TCO material can also be doped with a suitable dopant. In some embodiments, ZnO can be doped with any of aluminum (Al), gallium (Ga), boron (B), indium (In), yttrium (Y), scandium (Sc), fluorine (F), vanadium (V), silicon (Si), germanium (Ge), titanium (Ti), zirconium (Zr), hafnium (Hf), magnesium (Mg), arsenic (As), or hydrogen (H). In other embodiments, SnO₂ can be doped with antimony (Sb), F, As, niobium (Nb), or tantalum (Ta). In other embodiments, In2O3 can be doped with tin (Sn), Mo, Ta, tungsten (W), Zr, F, Ge, Nb, Hf, or Mg. In other embodiments, CdO can be doped with In or Sn. In other embodiments, GaInO₃ can be doped with Sn or Ge. In other embodiments, CdSb₂O₃ can be doped with Y. In other embodiments, ITO can be doped with Sn. Other embodiments include still other TCO materials and corresponding dopants. In some embodiments, the front contact layer 150 is from about 5 nm to about 3 μm thick. In some embodiments, the front contact layer 150 is formed by metal organic chemical vapor deposition (MOCVD). In other embodiments, the front contact 150 is formed by sputtering.

FIG. 1 also shows that the solar cell 100 includes a collection area 102 and an interconnect structure 104. The collection area includes all of the layers 120, 130, 145 and 150, for capturing photons. The interconnect structure includes a P1 scribe line separating the back contacts 120 of adjacent solar cells 100, and filled with absorber material. A P2 scribe line transmits current from the front contact 150 of a solar cell to the back contact 120 of an adjacent solar cell on the right hand side, to connect the solar cells 100 in series. In some embodiments, the P2 scribe line can have a width of from 10 μm to 300 μm, for example. The P2 scribe line is filled with the TCO material. A P3 scribe line separates the front contact 150, dielectric layer 145 and absorber layer 130 of the solar cell from like layers in the adjacent solar cell on the right side. The drawings are not to scale; the collection area 102 is much longer than the interconnect structure 104.

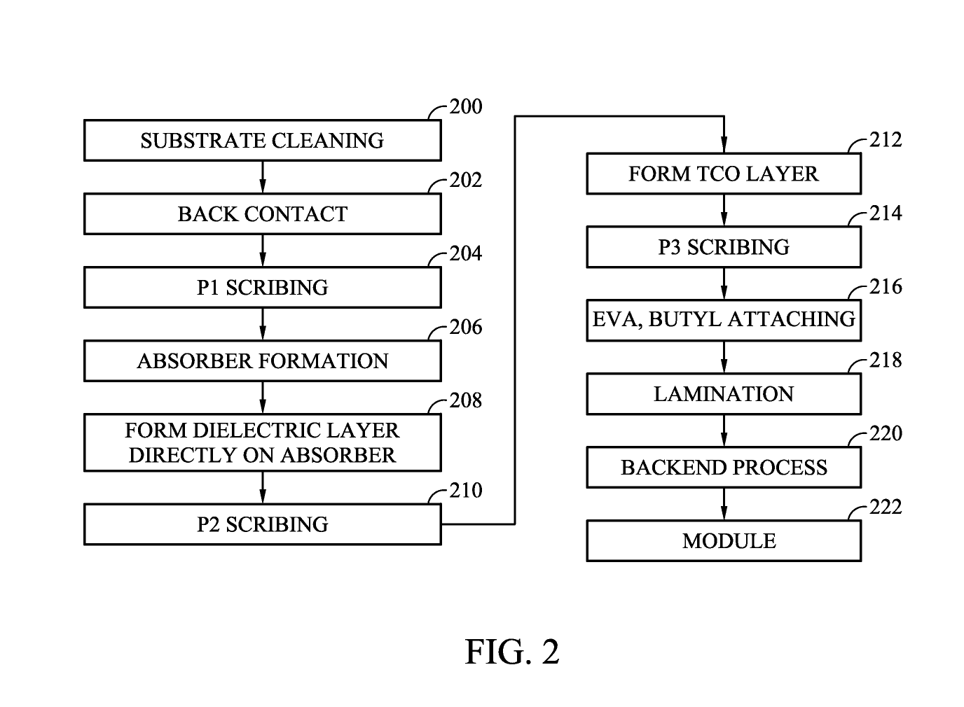

FIG. 2 is a flow chart of a method of making the solar panel 100 of FIG. 1, in accordance with some embodiments.

At step 200, the substrate is cleaned. In some embodiments, substrate 110 is cleaned by using detergent or chemical in either brushing tool or ultrasonic cleaning tool.

At step 202, back electrode layer 120 is then formed on a substrate 110 by sputtering, atomic layer deposition (ALD), chemical vapor deposition (CVD), or other suitable techniques.

At step 204, the P1 patterned scribe lines (not shown) are next formed in bottom electrode layer 120 to expose the top surface of substrate 110 as shown. Any suitable scribing method can be used such as, without limitation, mechanical scribing with a stylus or laser scribing.

At step 206, the p-type doped semiconductor light absorber layer 130 is next formed on top of bottom electrode layer 120. The absorber layer 130 material further fills the P1 scribe line and contacts the exposed top surface of substrate 110 to interconnect layer 130 to the substrate. Absorber layer 130 formed of CIGS can be formed by any suitable vacuum or non-vacuum process. Such processes include, without limitation, selenization, sulfurization after selenization (“SAS”), evaporation, sputtering electrodeposition, chemical vapor deposition, or ink spraying or the like.

At step 208, a dielectric layer 145, which can be a silicon oxide, an aluminum oxide or a hafnium oxide, for example, is then formed directly on absorber layer 130 to create an electrically active n-p junction. Dielectric layer 145 can be formed by sputtering, atomic layer deposition (ALD), chemical vapor deposition (CVD), or an electrolyte chemical bath deposition (CBD) process. A CBD process can form layers 145 using an electrolyte solution.

At step 210, the P2 scribe lines (not shown) are next cut through the dielectric layer 145 and absorber layer 130 to expose the top surface of the bottom electrode 120 within the open scribe line or channel. Any suitable method can be used to cut the P2 scribe line, including without limitation mechanical (e.g. cutting stylus) or laser scribing. The P2 scribe line will subsequently be filled with a conductive material from top electrode layer 150 to form the series interconnect between the top electrode 150 and the bottom electrode layer 120 of the adjacent solar cell.

At step 212, the front contact 150 is formed directly on the dielectric layer 145. In some embodiments, the step of forming the front contact 150 can include sputtering a layer of i-ZnO or AZO. In other embodiments, the step of forming the front contact 150 can include metal organic CVD (MOCVD) application of a layer of BZO. The top electrode 150 is thus configured to carry the collected charge to an external circuit (not shown). The P2 scribe line is also at least partially filled with the TCO material to form an electrical connection between the top electrode layer 150 of one solar cell and the bottom electrode 120 of the adjacent solar cell within the solar panel 100, creating an electron flow path.

At step 214, following formation of the TCO layer 150, the P3 scribe line is formed. The P3 scribe line extends through (from top to bottom) TCO top electrode layer 150, dielectric layer 145, absorber layer 130, and the bottom electrode layer 120 down to the top of substrate 110.

At step 216, a combination of ethylene vinyl acetate (EVA) and butyl are applied to seal the solar panel 100. The EVA and butyl encapsulant is applied directly onto the top electrode layer 150 in some embodiments. The EVA/butyl act as a suitable light transmitting encapsulant.

At step 218, heat and pressure are applied to laminate the EVA/butyl film to the front contact 150.

At step 220, additional back end of line processes can be performed. This can include laminating a top cover glass onto solar cell structure to protect the top electrode layer 150.

At step 222, suitable further back end processes can then be completed, which can include forming front conductive grid contacts and one or more anti-reflective coatings (not shown) above top electrode 150. The grid contacts protrude upwards through and beyond the top surface of any anti-reflective coatings for connection to external circuits. The solar cell fabrication process produces a finished and complete thin film solar cell module 100.

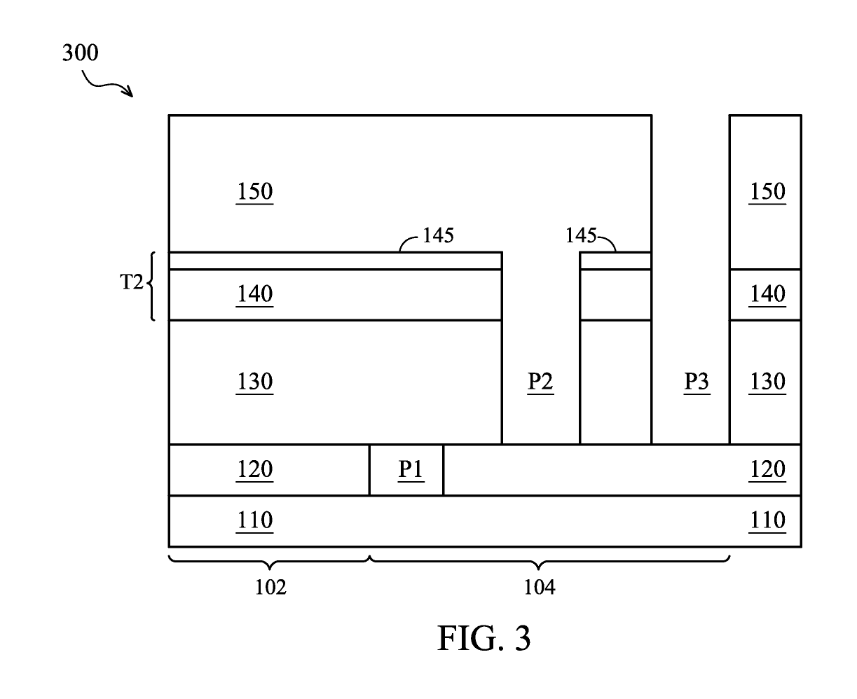

FIG. 3 is a cross sectional view of another solar cell 300 according to some embodiments. In FIGS. 1 and 3, like items are indicated by like reference numerals. The substrate 110, back contact 120, absorber layer 130, dielectric layer 145, front contact 150, and the P1, P2 and P3 scribe lines of solar cell 300 can be the same as described above with reference to solar cell 100 in FIG. 1, and except as specifically noted below, their descriptions are not repeated for brevity.

The solar cell 300 further comprises an embedded buffer layer 140 between the absorber layer 130 and the dielectric layer 145. Embedded buffer layer 140 includes any suitable buffer material, such as n-type semiconductors. In some embodiments, buffer layer 140 can include CdS, ZnS, zinc selenide (ZnSe), indium(III) sulfide (In₂S₃), indium selenide (In₂Se₃), or Zn₁₋ₓMgₓO, (e.g., ZnO). Other embodiments include still other buffer materials. In some embodiments, the embedded buffer layer 140 is applied by a wet process, such as chemical bath deposition (CBD).

In some embodiments, the embedded buffer layer 140 comprises cadmium sulfide or zinc sulfide, and the dielectric layer 145 comprises a silicon oxide, an aluminum oxide or a hafnium oxide. The buffer layer 140 is formed directly on the absorber layer 130, and the dielectric layer 145 is formed directly on the buffer layer 140. Layers 140 and 145 together form a “two-part buffer.” The buffer layer 140 can be selected to provide a passivation function, for example, if the top surface of the absorber layer 130 has a greater number of surface defects than the absorber 130 in FIG. 1. These surface defects are to be passivated (by bonding with the buffer material). But the buffer layer 140 is not solely responsible for providing a high Voc; the dielectric layer 145 can be selected to provide a high Voc, as described above.

The two-part buffer 140, 145 can have a combined thickness T2 much less than a typical thickness (e.g., 100 nm) of a buffer layer of CdS or ZnS (not shown) without a dielectric layer. For example, in some embodiments, the buffer layer 140 has a non-zero thickness less than 90 nm. and the dielectric layer 145 has a thickness from about 0.1 nm to about 10 nm, so that the total thickness T2 of the buffer layer 140 and dielectric layer 145 combined is less than 100 nm. In some embodiments, the buffer layer 140 has a thickness in a range from 3 nm to about 50 nm, and the dielectric layer 145 has a thickness from 0.1 nm to about 5 nm, so that the total thickness T2 is about 55 nm or less. In some embodiments, the buffer layer 140 has a thickness in a range from 3 nm to about 30 nm, and the dielectric layer 145 has a thickness from 0.1 nm to about 5 nm, so that the total thickness T2 is about 35 nm or less. In some embodiments, the buffer layer 140 has a thickness in a range from 3 nm to about 5 nm, and the dielectric layer 145 has a thickness from 1 nm to about 5 nm, so that the total thickness T2 is about 10 nm or less.

The two-part buffer layer 140, 145 permits the use of a dielectric layer to maintain high Voc and reduce the total thickness of the buffer layer (and improve light transmittance), even if the absorber layer 130 has a substantial number of surface defects that should be passivated by a CdS or ZnS layer 140. This combination can permit the use of a less expensive process for forming the absorber layer 130.

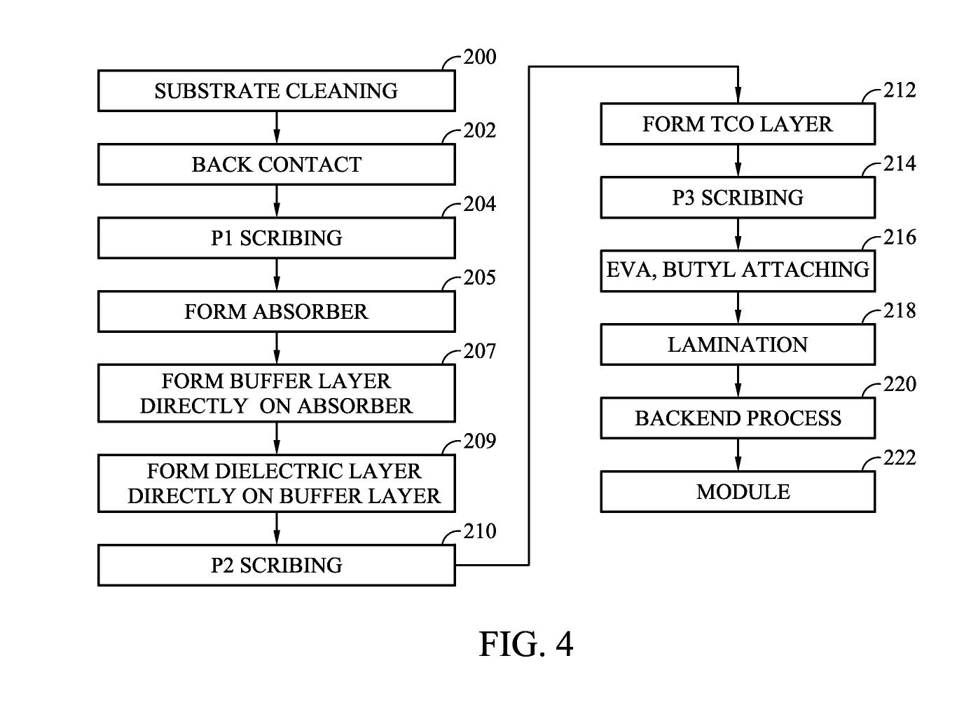

FIG. 4 is a flow chart of a method of fabricating the solar cell of FIG. 3, in accordance with some embodiments. The steps 200-206 and 210-222 can be the same as described above with respect to the method of FIG. 2, and like reference numerals indicate like steps. Descriptions of these steps are not repeated, for brevity. The method of FIG. 4 differs from the method of FIG. 2 in that step 208 of FIG. 2 is replaced by steps 207 and 209 in FIG. 4.

In step 208 of FIG. 2, the dielectric layer 145 is formed directly on the absorber layer 130. However, in step 207 of FIG. 4, the embedded buffer layer 140 is formed directly on the absorber 130; and in step 209, the dielectric layer 145 is formed directly on the embedded buffer layer 140.

Table 1 lists several examples of combinations of materials for the dielectric layer 145, with or without a buffer layer 140. In Table 1, examples 1, 2, 4 and 5 correspond to solar cell 100 of FIG. 1, and examples 3 and 6 correspond to solar cell 300 of FIG. 3.

TABLE 1

| | Example | Example | Example | Example | Example | Example |
|---|---|---|---|---|---|---|
| | structure | structure | structure | structure | structure | structure |
| | 1 | 2 | 3 | 4 | 5 | 6 |
| High doped | B: ZnO | B: ZnO | B: ZnO | B: ZnO | B: ZnO | B: ZnO |
| TCO | (Al: | (Al: | (Al: | (Al: | (Al: | (Al: |
| | ZnO) | ZnO) | ZnO) | ZnO) | ZnO) | ZnO) |
| Dielectric | SiOₓ | Al₂O₃ | SiOₓ | SiOₓ | Al₂O₃ | SiOₓ |
| or | | | CdS | | | CdS |
| Dielectric/ | | | (ZnS) | | | (ZnS) |
| Buffer | | | | | | |
| layer | | | | | | |
| Absorber | CIGS | CIGS | CIGS | CdTe | CdTe | CdTe |
| layer | | | | | | |
| Bottom | Mo | Mo | Mo | Cu | Cu | Cu |
| electrode | | | | | | |

In some embodiments, a solar cell in accordance with example 1 above with a 5 nm SiO₂ dielectric layer 145 can improve efficiency, for example, from about 15% to about 16%, which is a percentage increase of 3% to 5%. In some embodiments, a solar cell in accordance with example 2 above with a 5 nm Al₂O₃ dielectric layer 145 can improve efficiency by 0.8%. The difference between the efficiency using SiO₂ and the efficiency using Al₂O₃ is due to the difference in band gap between the two materials.

The methods described above can be applied for solar cells having p-n or p-i-n junctions, metal-insulator-semiconductor (MIS) structures, multi-junction structures or the like.

In the embodiments described above, the buffer layer of a thin film photovoltaic solar cell is replaced or supplemented by a dielectric layer. A dielectric layer with a small thickness can support a high electrical field and prevent shunts (leakage) between the front contact and the back contact. If a dielectric layer replaces the buffer layer, the dielectric layer can be thinner than a buffer layer formed of a material such as cadmium sulfide (CdS) or zinc sulfide (ZnS). If a dielectric layer supplements the buffer layer, the total thickness of dielectric layer and buffer layer combined can be thinner than a CdS or ZnS buffer layer without the dielectric layer. Because the dielectric layer (or combination of buffer layer and dielectric layer) can be thinner than a buffer layer without the dielectric layer, a high Voc can be maintained while increasing light transmittance. The overall efficiency of the solar cell can be increased by up to about 5%. For solar cells having a high quality absorber surface, the CdS or ZnS buffer layer can be eliminated, providing a more environmentally friendly solar cell and fabrication process.

Thus, using a dielectric layer 145 as described herein, a high electrical field strength and high optical transmittance property can further boost solar cell efficiency. The application of a thin layer of dielectric material can provide a high electrical field strength. The optical transmittance of the buffer layer comprising a dielectric material as described above can be improved by the reduced thickness. The use of dielectric material as buffer layer permits fabrication of the device using a Cadmium-free process.

In some embodiments, a solar cell comprises: a back contact layer, an absorber layer above the back contact layer, a dielectric layer above the absorber layer, and a front contact layer above the dielectric layer.

In some embodiments, a solar cell comprises: a back contact layer, an absorber layer above the back contact layer, a buffer layer on the absorber layer, a dielectric layer on the buffer layer, and a front contact layer on the dielectric layer.

In some embodiments, a method of fabricating a solar cell comprises: forming a back contact layer over a substrate, forming an absorber layer above the back contact layer, forming a dielectric layer above the absorber layer, and forming a front contact layer above the dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A solar cell, comprising:
a back contact layer;
an absorber layer above the back contact layer;
a dielectric layer above the absorber layer; and
a front contact layer above the dielectric layer.

2. The solar cell of claim 1, wherein the dielectric layer is formed directly on the absorber layer, and the front contact layer is formed directly on the dielectric layer.

3. The solar cell of claim 2, wherein the dielectric layer comprises one of the group consisting of a silicon oxide, an aluminum oxide and a hafnium oxide.

4. The solar cell of claim 2 wherein the dielectric layer has a thickness from about 0.1 nm to about 10 nm.

5. The solar cell of claim 1, wherein the dielectric layer comprises a material having a band gap greater than 3 eV.

6. The solar cell of claim 1, wherein the dielectric layer comprises a material having a dielectric constant in a range from about 3 to about 11.

7. The solar cell of claim 1, further comprising a buffer layer between the absorber layer and the dielectric layer.

8. The solar cell of claim 7, wherein the dielectric layer comprises one of the group consisting of a silicon oxide, an aluminum oxide and a hafnium oxide.

9. The solar cell of claim 6, wherein the buffer layer comprises one of the group consisting of cadmium sulfide and zinc sulfide.

10. The solar cell of claim 8 wherein the dielectric layer has a thickness from about 0.1 nm to about 10 nm.

11. The solar cell of claim 10 wherein the buffer layer has a non-zero thickness less than 90 nm.

12. The solar cell of claim 9 wherein the buffer layer has a thickness in a range from about 3 nm to about 50 nm.

13. The solar cell of claim 1, wherein:
the dielectric layer is formed directly on the absorber layer, and the front contact layer is formed directly on the dielectric layer;
the dielectric layer has a thickness from about 0.1 nm to about 10 nm;
the dielectric layer comprises a material having a band gap greater than 3 eV; and
the dielectric layer comprises a material having a dielectric constant in a range from about 3 to about 11

14. A solar cell comprising:
a back contact layer;
an absorber layer above the back contact layer;
a buffer layer on the absorber layer;
a dielectric layer on the buffer layer; and
a front contact layer on the dielectric layer.

15. The solar cell of claim 14, wherein:
the dielectric layer comprises one of the group consisting of a silicon oxide, an aluminum oxide and a hafnium oxide; and
the buffer layer comprises one of the group consisting of cadmium sulfide and zinc sulfide.

16. The solar cell of claim 15 wherein
the buffer layer has a thickness in a range from about 3 nm to about 50 nm; and
the dielectric layer has a thickness from about 1 nm to about 5 nm.

17. A method of fabricating a solar cell, comprising:
forming a back contact layer over a substrate;
forming an absorber layer above the back contact layer;
forming a dielectric layer above the absorber layer; and
forming a front contact layer above the dielectric layer.

18. The method of claim 17, wherein the dielectric layer is formed directly on the absorber layer, and the front contact layer is formed directly on the dielectric layer.

19. The method of claim 17, further comprising forming a buffer layer on the absorber layer, wherein the dielectric layer is formed on the buffer layer.

20. The method of claim 17, wherein the dielectric layer comprises one of the group consisting of a silicon oxide, an aluminum oxide and a hafnium oxide.
